(19) United States
(12) Patent Application Publication
(10) Pub. No.: US 2026/0271708 A1
(43) Pub. Date: Sep. 10, 2026

(54) COOLING STRUCTURE FOR ELECTRONIC COMPONENT

(71) Applicant: SEA SONIC ELECTRONICS CO., LTD., Taipei (TW)

(72) Inventor: Chi-Hao CHANG, Taipei (TW)

(21) Appl. No.: 19/071,079

(22) Filed: Mar. 5, 2025

(51) Int. Cl. H01L 23/367; H01L 23/373; H01L 23/498

(52) U.S. Cl. CPC H10W 40/226; H10W 40/258; H10W 70/479

(57) ABSTRACT

A cooling structure for electronic component includes an electronic component, a heat sink configured to establish a thermal conduction relationship with the electronic component, and a circuit board. The electronic component includes a package casing, a plurality of pins, and a top-mounted heat sink. The circuit board is provided with a plurality of first copper coils for bonding the pins, and a second copper coil provided for bonding the heat sink. The second copper coil is divided into a first portion provided for bonding the heat sink and a second portion connected to the first portion, the second portion contacts the package casing of the electronic component without forming a bonding connection, when the electronic component is mounted on the circuit board, thereby improving a cooling effect of the electronic component. Further, the invention can be implemented with a plurality of electronic components.

### FIELD OF THE INVENTION

The invention relates to a cooling structure, specifically the cooling structure for electronic component.

### BACKGROUND OF THE INVENTION

As technology advances, modern circuit boards commonly exhibit high power density characteristics, with electronic components densely arranged on the circuit board. When the product operates, the temperature of the electronic components rises accordingly, leading to operational errors caused by excessive heat, a phenomenon commonly referred to in the industry as “thermal shutdown.”

In response to this issue, existing patents TW M339199U and TW M258342U propose technical solutions to enhance the heat dissipation of electronic components. For instance, TW M339199U discloses a design where a heat conduction layer is arranged around the electronic component, and pins of the electronic component are soldered to the heat conduction layer to dissipate heat. Additionally, the patent includes a heat sink on a circuit board that corresponds to the heat conduction layer to further dissipate heat from the electronic component.

However, the aforementioned technologies are limited to electronic component with a vertical structure, and only teach the concept of transferring heat through the pin to the circuit board. With technological evolution, when electronic component adopts a horizontal structure, heat transfer remains limited to the pins, and the heat accumulated on the package casing cannot be rapidly dissipated. This limitation prevents such electronic component from achieving optimal heat dissipation efficiency. Furthermore, during the actual operation of electronic component, heat typically accumulates on the package casing, which leads to operational errors. The prior art fails to address the issue of inadequate heat dissipation for electronic component.

### SUMMARY OF THE INVENTION

A main object of the invention is to improve the problem of poor heat dissipation of conventional electronic components.

In order to achieve the above object, the invention provides a cooling structure for electronic component, comprising an electronic component, a heat sink, and a circuit board. The electronic component includes a package casing, a plurality of pins exposed from the package casing, a top-mounted heat sink exposed from the package casing. The heat sink is configured to establish a thermal conduction relationship with the electronic component. The circuit board is provided with a plurality of first copper foils for bonding the pins of the electronic component and a second copper foil for bonding the heat sink. The second copper foil is divided into at least one first portion for bonding the heat sink and a second portion connected to the at least one first portion. The second portion is in contact with the package casing of the electronic component without forming a bonding connection, when the electronic component is mounted on the circuit board.

In one example, the heat sink is straddled on the electronic component, the heat sink includes two bonding feet, the second copper coil includes two first portions, and the second portion of the second copper coil is positioned between the two first portions.

In one example, at least one of the two first portions includes a heat sink bonding area and an auxiliary cooling area connected to the heat sink bonding area.

In one example, the first copper coils are divided into two groups spaced apart, at least three sides of each of the two groups are provided with the second copper coil, and the second portion of the second copper coil is positioned between the two groups.

In one example, each of the two first portions includes a heat sink bonding area and an auxiliary cooling area connected to the heat sink bonding area.

In one example, the top-mounted heat sink is in direct contact with the heat sink.

In one example, the cooling structure for electronic component further includes an auxiliary thermal conduction member positioned between the electronic component and the heat sink, and the auxiliary thermal conduction member is in direct contact with the top-mounted heat sink.

In one example, the cooling structure for electronic component includes at least two electronic components, and the heat sink is straddled on the at least two electronic components to form a thermal conduction relationship, the second copper coil is divided into a plurality of first portions and a plurality of second portions, each of the second portions is respectively connected to two of the first portions disposed adjacently.

In one example, each of the first portions comprises a heat sink bonding area and an auxiliary cooling area connected to the heat sink bonding area.

Through the above-mentioned implementation of the present invention, compared with the conventional method, the following characteristics are possessed: the electronic component of the present invention is provided with the top-mounted heat sink to assist in cooling the electronic component. In the meantime, when the electronic component is mounted on the circuit board, the package casing of the electronic component contacts the second portion of the second copper coil without forming a bonding connection, thereby specifically improving a cooling effect of the electronic component. In addition, in the invention, a plurality of electronic components can be adopted to implement in a parallel arrangement in practice.

### BRIEF DESCRIPTION OF THE DRAWINGS

FIG. 1 is perspective view of the first example of the invention.

FIG. 2 is a cross-sectional view of the first example of the invention.

FIG. 3 is a perspective view of the second example of the invention.

FIG. 4 is an exploded view of the second example of the invention.

FIG. 5 is a cross-sectional view of the second example of the invention.

FIG. 6 is a top view of the second example of the invention.

FIG. 7 is a perspective view of the third example of the invention.

### DETAILED DESCRIPTION OF THE PREFERRED EMBODIMENTS

The detailed description and technical content of the invention are as follows, with reference to the accompanying figures:

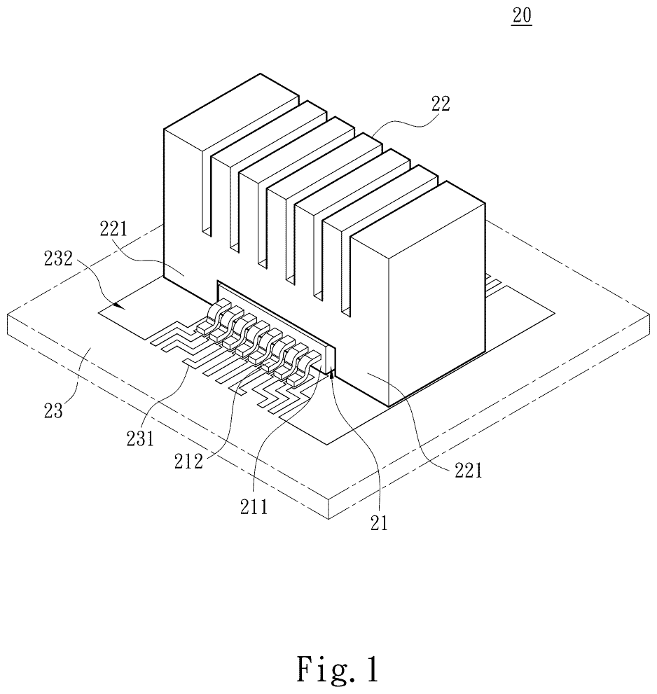

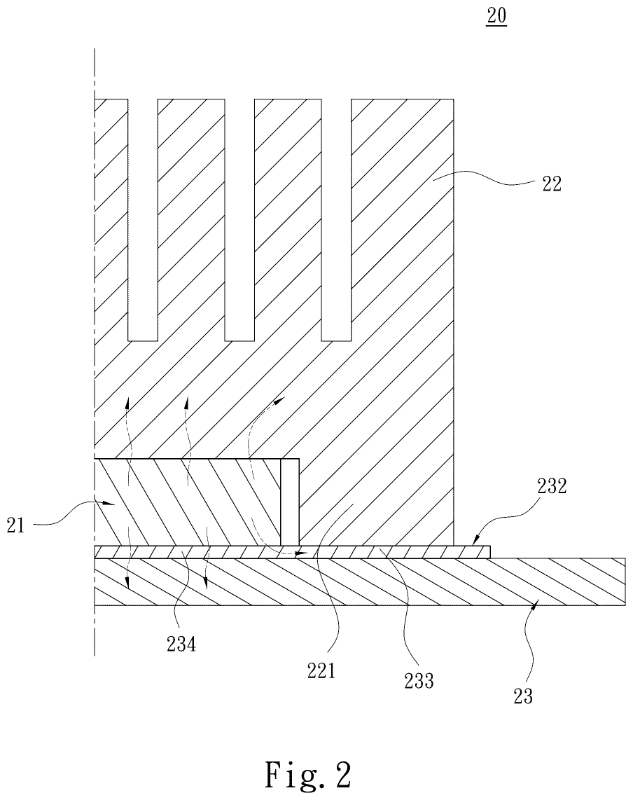

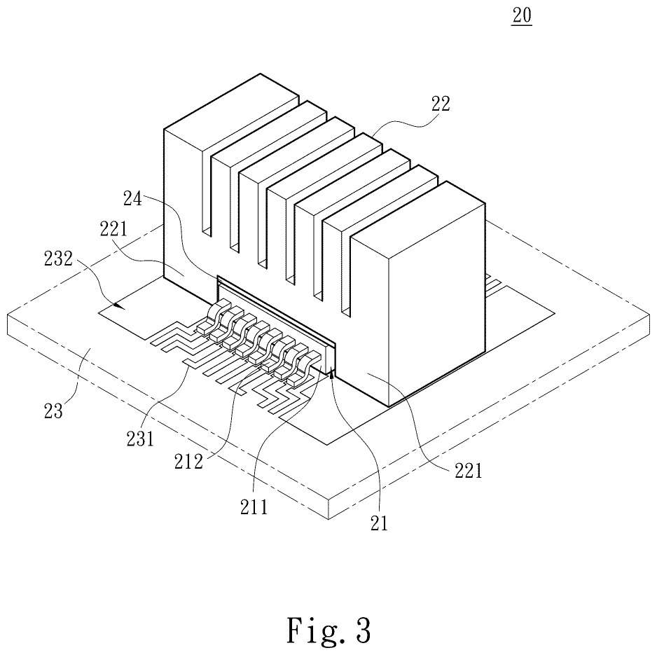

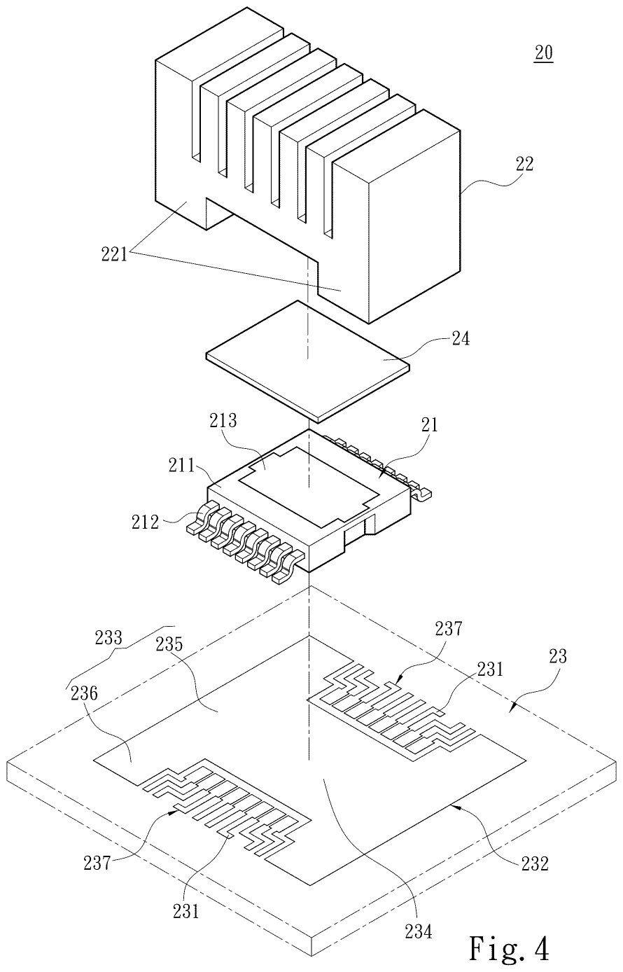

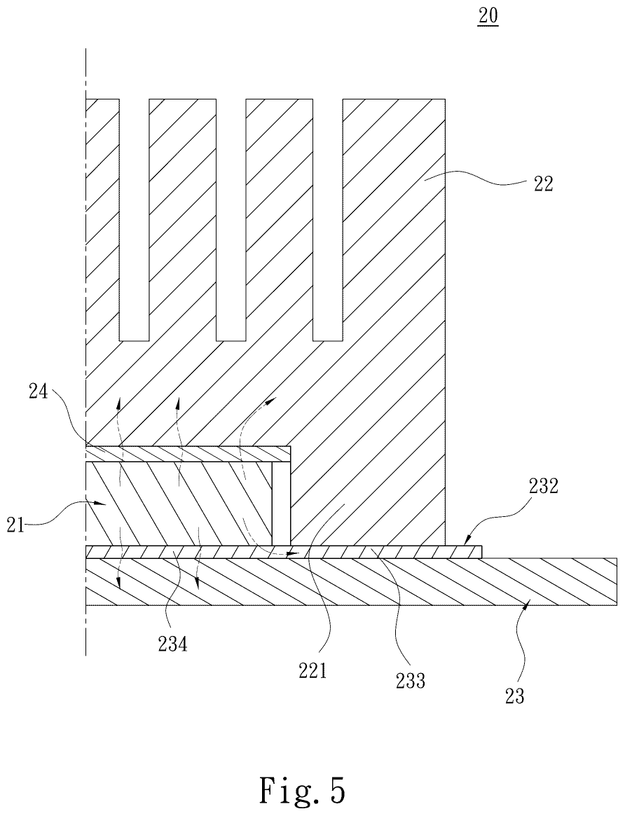

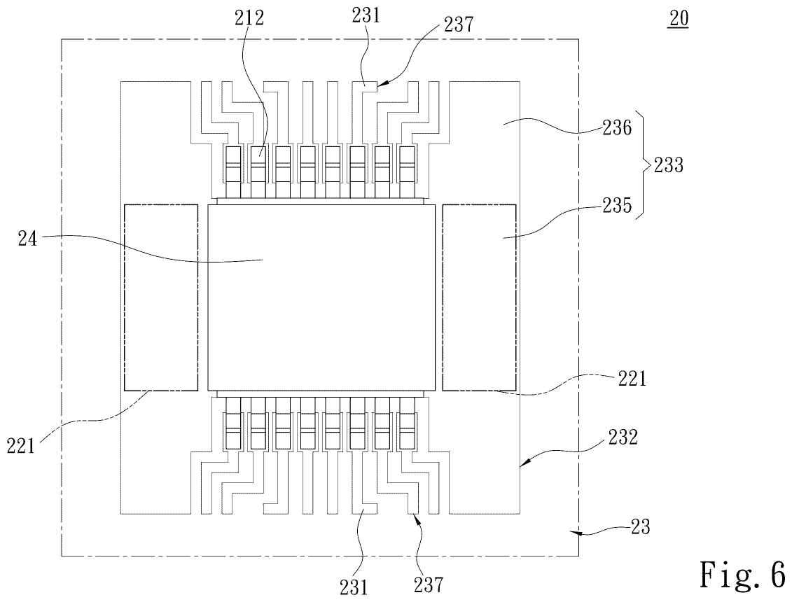

Please refer to FIG. 1, FIG. 2, FIG. 3, FIG. 4, FIG. 5, and FIG. 6. The invention provides a cooling structure for electronic component, 20 including an electronic component 21, a heat sink 22, and a circuit board 23. The electronic component 21 includes a package casing 211, a plurality of pins 212 exposed from the package casing 211, and a top-mounted heat sink 213 exposed from the package casing 211. The electronic component 21 is a surface-mounted device (SMD). The electronic component 21 is soldered onto the circuit board 23 via the pins 212 during a surface-mount process. It should be noted that, although the figures illustrate the electronic component 21 in the form of a chip, in practice, the electronic component 21 may also be a MOS switch or other components implemented by using surface-mount technology. The pins 212 may be positioned on both sides of the package casing 211, as depicted in the figures, or may be located on the same side, similar to a MOS switch. The top-mounted heat sink 213 is positioned on a top surface of the package casing 211. When the electronic component 21 operates to generate heat energy, causing the package casing 211 to increase in temperature, the top-mounted heat sink 213 helps dissipate heat from the package casing 211. Additionally, the heat sink 22 is configured to establish a thermal conduction relationship with the electronic component 21. A connection between the heat sink 22 and the electronic component 21 is not specifically limited, as long as it is sufficient to facilitate thermal conduction. For example, the heat sink 22 may be in direct contact with the top-mounted heat sink 213 of the electronic component 21, allowing heat from the electronic component 21 to transfer directly to the heat sink 22 through the top-mounted heat sink 213. In another example, as illustrated in FIG. 3, FIG. 4, FIG. 5, and FIG. 6, the heat sink 22 and the electronic component 21 may utilize an auxiliary thermal conduction member 24 additionally disposed for heat transfer. The auxiliary thermal conduction member 24 is positioned between the heat sink 22 and the electronic component 21, making direct contact with the top-mounted heat sink 213 to transfer heat from the top-mounted heat sink 213 to the heat sink 22. The auxiliary thermal conduction member 24 may be a thermal pad, thermal putty, etc.

The circuit board 23 is provided with a plurality of first copper foils 231 and a second copper foil 232. The electronic component 21 and the heat sink 22 are mounted on the circuit board 23 by using an automated surface-mount technology. The first copper foils 231 and the second copper foil 232 are printed on positions of the circuit board 23 where the electronic component 21 and the heat sink 22 to be bonded. After the electronic component 21 and the heat sink 22 enter an automated material belt, the first copper foils 231 are provided for bonding the pins 212 of the electronic component 21, and the second copper foil 232 is provided for bonding the heat sink 22. After bonding, the first copper foils 231 establish an electrical connection with the pins 212, allowing the transmission of electrical signals from the electronic component 21. The second copper foil 232 is divided into at least one first portion 233 for bonding the heat sink 22, and a second portion 234 connected to the at least one first portion 233. The at least one first portion 233 forms a thermal conduction relationship with the heat sink 22. The second portion 234 is positioned beneath the package casing 211 of the electronic component 21 when the electronic component 21 is mounted on the circuit board 23. The second portion 234 contacts the package casing 211 of the electronic component 21 but does not form a bonding connection, thereby assisting in cooling the package casing 211.

As can be seen from the foregoing, when the electronic component 21 is in operation, the pins 212 transmit electrical signals through the first copper foils 231. When the temperature of the electronic component 21 rises, the heat energy in the package casing 211 can be transferred from the top-mounted heat sink 213 to the heat sink 22, and can also be transferred from the package casing 211 to the second portion 234 of the second copper foil 232, thereby accelerating the dissipation of the heat energy on the electronic component 21, and enabling the electronic component 21 to obtain a good cooling effect.

Compared to the conventional method, the present invention accelerates the heat dissipation of the package casing 211 through the top-mounted heat sink 213 and the second portion 234 of the second copper foil 232, so that the operation failure of the electronic component 21 caused by heat energy is reduced.

Continuing from the above, please refer to FIG. 1, FIG. 2, FIG. 3, FIG. 4, FIG. 5, and FIG. 6. The heat sink 22 of the invention is straddled on the electronic component 21. Said “straddle” refers to that the heat sink 22 includes two bonding feet 221 located on two sides of the electronic component 21, so that the heat sink 22 forms an arrangement of straddling the electronic component 21. At this time, the second copper foil 232 includes two first portions 233, and the second portion 234 of the second copper foil 232 is located between the two first portions 233. In one example, at least one of the two first portions 233 includes a heat sink bonding area 235 and an auxiliary cooling area 236. The heat sink bonding area 235 is provided for bonding one of the two bonding feet 221. The auxiliary cooling area 236 is connected to the heat sink bonding area 235 but is not bonded to the heat sink 22. By arranging the auxiliary cooling area 236, areas of the two first portions 233 are larger than areas of the two bonding feet 221, thereby assisting in cooling the heat sink 22.

In another example, the pins 212 in the invention are located on both sides of the package casing 211, the first copper foils 231 are divided into two groups 237 spaced apart, at least three sides of each of the two groups 237 are provided with the second copper foil 232, and the second portion 234 of the second copper foil 232 is located between the two groups 237. When the electronic component 21 is disposed on the circuit board 23, the package casing 211 is positioned above the second portion 234 of the second copper foil 232. The two groups 237 are respectively located on two sides of the package casing 211 and provide the pins 212 for disposing. To further explain, in this example, the second copper foil 232 is configured into an “H” shape, and the two groups 237 are respectively located at two opposite sides of the “H” shape. Furthermore, each of the two first portions 233 of the second copper foil 232 includes the heat sink bonding area 235 and the auxiliary cooling area 236.

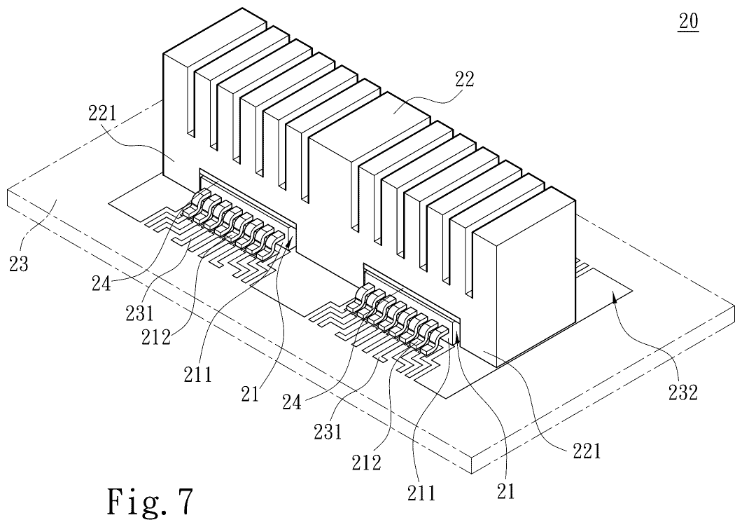

Please refer to FIG. 5, FIG. 6, and FIG. 7. In one example, the electronic component 21 in the invention can be designed in multiple configurations according to the implementation. Specifically, the cooling structure for electronic component 20 includes at least two electronic components 21. The at least two electronic components 21 are arranged in parallel and have the same potential. The heat sink 22 is straddle on the at least two electronic components 21, and forms a thermal conduction relationship between the heat sink 22 and the at least two electronic components 21. The second copper foil 232 is divided into a plurality of first portions 233 and a plurality of second portions 234. Each of the second portions 234 is respectively connected to two of the first portions 233 disposed adjacently. Furthermore, each of the first portions 233 includes the heat sink bonding area 235 and the auxiliary cooling area 236 to enhance the cooling effect of the heat sink 22.

What is claimed is:

1. A cooling structure for electronic component, comprising:
an electronic component, comprising a package casing, a plurality of pins exposed from the package casing, and a top-mounted heat sink exposed from the package casing:
a heat sink, configured to establish a thermal conduction relationship with the electronic component; and
a circuit board, comprising a plurality of first copper foils for bonding the pins of the electronic component and a second copper foil for bonding the heat sink, the second copper foil being divided into at least one first portion for bonding the heat sink and a second portion connected to the first portion, and the second portion contacting the package casing of the electronic component without forming a bonding connection, when the electronic component mounted on the circuit board.

2. The cooling structure for electronic component as claimed in claim 1, wherein the heat sink is straddled on the electronic component, the heat sink comprises two bonding feet, the second copper foil comprises two first portions, and the second portion of the second copper foil is positioned between the two first portions.

3. The cooling structure for electronic component as claimed in claim 2, wherein at least one of the two first portions comprises a heat sink bonding area and an auxiliary cooling area connected to the heat sink bonding area.

4. The cooling structure for electronic component as claimed in

2. wherein the first copper coils are divided into two groups spaced apart, at least three sides of each of the two groups are provided with the second copper coil, and the second portion of the second copper coil is located between the two groups.

5. The cooling structure for electronic component as claimed in claim 4, wherein each of the two first portions comprises a heat sink bonding area and an auxiliary cooling area connected to the heat sink bonding area.

6. The cooling structure for electronic component as claimed in claim 1, wherein the top-mounted heat sink is in direct contact with the heat sink.

7. The cooling structure for electronic component as claimed in claim 1, further comprising an auxiliary thermal conduction member positioned between the electronic component and the heat sink, wherein the auxiliary thermal conduction member is in contact with the top-mounted heat sink.

8. The cooling structure for electronic component as claimed in claim 1, wherein the cooling structure for electronic component comprises at least two electronic components, and the heat sink is straddled on the at least two electronic components, the heat sink forms the thermal conduction relationship with the at least two electronic components, the second copper coil is divided into a plurality of first portions and a plurality of second portions, and each of the second portions is respectively connected to two of the first portions disposed adjacently.

9. The cooling structure for electronic component as claimed in claim 8, wherein each of the first portions comprises a heat sink bonding area and an auxiliary cooling area connected to the heat sink bonding area.
